(19) United States
(12) Patent Application Publication
(10) Pub. No.: US 2014/0130575 A1
(43) Pub. Date: May 15, 2014

(54) METHOD AND APPARATUS FOR ELECTRICALLY INDICATING A GAS CHARACTERISTIC

(71) Applicant: Franklin Fueling Systems, Inc., Madison, WI (US)

(72) Inventors: James A. Webber, Saco, ME (US); John P. Eastman, Scarborough, ME (US)

(73) Assignee: Franklin Fueling Systems, Inc., Madison, WI (US)

(21) Appl. No.: 14/075,760

(22) Filed: Nov. 8, 2013

Related U.S. Application Data
(60) Provisional application No. 61/724,704, filed on Nov. 9, 2012.
(60) Provisional application No. 61/752,185, filed on Jan. 14, 2013.

(51) Int. Cl. G01R 31/327; G01N 27/74

(52) U.S. Cl. CPC G01R 31/327; G01N 27/74
USPC 73/31.04

(57) ABSTRACT

An apparatus for generating a signal representing one of the density and the pressure of gas within a high voltage circuit breaker based on a dial position of a pressure switch includes a clip configured to mechanically couple to the dial, the clip including a magnet, and lens assembled into the switch between the switch housing and an outer component of the switch. The lens includes a sensor positioned within a cavity of the lens in alignment with the clip magnet to detect the position of the pressure switch dial from a magnetic orientation of the magnet, and circuitry for converting the detected position into an electric signal.

### RELATED APPLICATIONS

This application claims the benefit of U.S. Provisional Application Ser. No. 61/724,704, filed Nov. 9, 2012, titled METHOD AND APPARATUS FOR DETERMINING GAS DENSITY, docket FEC0211-01-US, and claims the benefit of U.S. Provisional Application Ser. No. 61/752,185, filed Jan. 14, 2013, titled METHOD AND APPARATUS FOR DETERMINING GAS DENSITY, docket FEC0211-02-US, the disclosures of which are expressly incorporated by reference herein.

### FIELD

The present disclosure relates generally to methods and apparatuses for monitoring circuit breakers and more particularly to indicating a gas characteristic associated with circuit breakers by converting a mechanical indication of the characteristic into electrical signals for use by a monitoring system.

### BACKGROUND

High voltage circuit breakers have an open state wherein electricity is not transmitted through the circuit breaker and a closed state wherein electricity is transmitted through the circuit breaker. To transition between these states electrical conductors are either brought into contact with each other or separated relative to each other. As the circuit breaker transitions between these states one or more undesired arcs of electrical energy may be transmitted between the electrical conductors.

It is known to house the electrical conductors within a housing that is filled with an arc quenching fluid. An exemplary arc quenching fluid is a gas containing Sulphur-Hexa-Fluoride (“SF6”). The SF6 gas acts to reduce the occurrence or intensity of undesired arc events which contribute to the degradation of the circuit breaker components. Over time the circuit breaker components need to be replaced or the arc quenching gas needs to be refilled.

It is further known to use a pressure switch as a mechanism for blocking operation of the circuit breaker when the SF6 gas is unacceptably low. Such pressure switches are coupled pneumatically to the circuit breaker to sense the pressure of SF6 gas therein and include a temperature sensor which is used to temperature compensate the SF6 gas pressure measurements. In addition to including mechanical switching to disable the circuit breaker when the level of SF6 gas is unacceptably low (as indicated by the pressure switch's temperature compensated gas pressure measurements), the pressure switches typically include a mechanical dial pointer that rotates through an arc on a labeled face plate to visually indicate the measured gas pressure.

While the visual indication of SF6 gas pressure is useful, it would also be desirable to provide electrical signals to a monitoring system which include information about the pressure and temperature of the SF6 gas as sensed by the pressure switch. An electrical representation of the dial pointer position would provide the monitoring system the ability to retain a history of operation of the pressure switch, identify trends relating to the SF6 gas in the circuit breaker, generate and transmit alarms when the SF6 gas is unacceptably low, and expand the usefulness of existing hardware in the field (i.e., extend the useful life).

### SUMMARY

An exemplary method of the present disclosure of monitoring a circuit breaker is provided. The circuit breaker including a first conductive element electrically coupled to a first power line and a second conductive element electrically coupled to a second power line. A connection of the first conductive element and the second conductive element being positioned in a housing including an arc quenching fluid. At least one characteristic of the arc quenching fluid being monitored by a pressure switch. The second conductive element being movable relative to the first conductive element thereby providing a closed state of the circuit breaker when the first conductive element is in contact with the second conductive element and an open state of the circuit breaker when the first conductive element is spaced apart from the second conductive element. The method comprising the step of monitoring at least one characteristic of the arc quenching fluid by monitoring an angular orientation of a dial pointer of the pressure switch with a non-contact sensor. In one example, the method further comprises the step of monitoring at least one characteristic of the current flowing between the first power line and the second power line.

In a variation thereof, the step of monitoring at least one characteristic of the arc quenching fluid by monitoring a dial pointer of the pressure switch with the non-contact sensor includes the steps of coupling a magnet to the dial pointer, the magnet rotating with the dial pointer; and positioning the non-contact sensor in proximity to the magnet, but spaced apart from the magnet. The non-contact sensor monitoring an angular orientation of the magnet which is indicative of the angular orientation of the dial pointer.

In a further variation thereof, the pressure switch includes a face plate and a lens. The dial pointer is positioned between the face plate and the lens. The non-contact sensor is positioned between an outer surface of the lens and the dial pointer. In a refinement thereof, the steps of monitoring at least one characteristic of the current flowing between the first power line and the second power line; and monitoring at least one characteristic of the arc quenching fluid are performed by a monitoring unit separate from the pressure switch. Further, the method further comprises the step of receiving with the monitoring unit an indication of the angular orientation of the dial pointer.

In another variation thereof, the pressure switch includes a face plate and a lens. The dial pointer is positioned between the face plate and the lens. The non-contact sensor is positioned within a cavity of the lens and in alignment with the magnet. In a refinement thereof, the lens includes a terminal block and the method further includes the step of electrically coupling the non-contact sensor to the terminal block. In a further refinement thereof, the steps of monitoring at least one characteristic of the current flowing between the first power line and the second power line; and monitoring at least one characteristic of the arc quenching fluid are performed by a monitoring unit separate from the pressure switch. The monitoring unit being electrically coupled to the non-contact sensor through the terminal block.

In still another variation thereof, the pressure switch includes a face plate and a lens and the method further comprises the steps of removing the lens of the pressure switch; and assembling a replacement lens to the pressure switch. The replacement lens including the non-contact sensor positioned within a cavity of the lens and in alignment with the magnet. In a refinement thereof, the pressure switch includes an outer component and the method further comprises the step of removing the outer component of the pressure switch. Further, the step of assembling the replacement lens to the pressure switch includes the steps of positioning the replacement lens between the housing of the pressure switch and the outer component of the pressure switch and securing the outer component to the housing. In a further refinement thereof, the step of securing the outer component to the housing includes the step of securing the outer component to the housing with a plurality of fasteners which extend through respective openings in the replacement lens. In still a further refinement thereof, the replacement lens includes a wiring tunnel connecting a side of the replacement lens and the cavity and the method further comprises the steps of routing wires through the wiring tunnel, the wires connected to the non-contact sensor. In yet a further refinement thereof, the steps of monitoring at least one characteristic of the current flowing between the first power line and the second power line; and monitoring at least one characteristic of the arc quenching fluid are performed by a monitoring unit separate from the pressure switch. The monitoring unit being electrically coupled to the non-contact sensor through the wires.

In yet another variation thereof, the pressure switch includes a face plate and a lens. The dial pointer is positioned between the face plate and the lens. The method further comprises the step of coupling the non-contact sensor to the pressure switch. The lens is positioned between the non-contact sensor and the dial pointer.

In another exemplary embodiment of the present disclosure, a system for monitoring a circuit breaker including a first conductive element electrically coupled to a first power line and a second conductive element electrically coupled to a second power line is provided. A connection of the first conductive element and the second conductive element is positioned in a housing including an arc quenching fluid. At least one characteristic of the arc quenching fluid being monitored by a pressure switch. The second conductive element being movable relative to the first conductive element thereby providing a closed state of the circuit breaker when the first conductive element is in contact with the second conductive element and an open state of the circuit breaker when the first conductive element is spaced apart from the second conductive element. The system comprising a monitoring unit; a magnet coupled to the dial pointer of the pressure switch, the magnet rotating with the dial pointer, an angular orientation of the dial pointer providing an indication of at least one characteristic of the arc quenching fluid; and a sensor positioned in proximity to the magnet, but spaced apart from the magnet, the sensor monitoring an angular orientation of the magnet which is indicative of the angular orientation of the dial pointer of the pressure switch, an indication of the angular orientation of the dial pointer being provided to the monitoring unit. In an example thereof, the monitoring unit is electrically coupled to at least one of the first power line and the second power line to monitor at least one characteristic of the current flowing between the first power line and the second power line.

In one variation, the pressure switch includes a face plate and a lens. The dial pointer is positioned between the face plate and the lens. The non-contact sensor being positioned between an outer surface of the lens and the dial pointer.

In another variation, the pressure switch includes a face plate and a lens. The dial pointer is positioned between the face plate and the lens. The non-contact sensor is positioned within a cavity of the lens and in alignment with the magnet. In a further variation thereof, the lens includes a terminal block. The non-contact sensor is electrically coupled to the terminal block. In a refinement thereof, the monitoring unit is electrically coupled to the non-contact sensor through the terminal block. In a further refinement thereof, the pressure switch includes an outer component and the lens is positioned between the housing of the pressure switch and the outer component of the pressure switch. In another further variation thereof, the lens includes a wiring tunnel connecting a side of the lens and the cavity, the non-contact sensor and the monitoring unit being electrically coupled through wires extending through the tunnel.

In a further example thereof, the pressure switch includes a face plate and a lens. The dial pointer is positioned between the face plate and the lens. The lens is positioned between the non-contact sensor and the dial pointer.

In a further exemplary embodiment of the present disclosure, an apparatus for generating a signal representing one of the density and pressure of gas within a high voltage circuit breaker based on a dial position of a pressure switch is provided. The pressure switch having an outer component and a housing. The pressure switch is coupled to the circuit breaker. The apparatus comprising a magnet mechanically coupled to the dial of the pressure switch; and a lens assembled into the pressure switch between the housing of the pressure switch and the outer component of the pressure switch, and circuitry to convert the detected position into an electric signal. The lens including a sensor positioned within a cavity of the lens in alignment with the magnet to detect the position of the pressure switch dial indicator from a magnetic orientation of the magnet. In one example, the magnet is carried by a clip which is configured to mechanically couple to the dial indicator of the pressure switch. In another example, the lens includes a terminal block, the non-contact sensor being electrically coupled to the terminal block. In still another example, the lens includes a wiring tunnel connecting a side of the lens and the cavity. The non-contact sensor being electrically coupled to wires extending through the tunnel.

In one embodiment, the present disclosure provides an apparatus for generating a signal representing one of the density and the pressure of gas within a high voltage circuit breaker based on a dial position of a pressure switch having an outer component and a housing and being coupled to the circuit breaker, comprising a clip configured to mechanically couple to the dial of the pressure switch, the clip including a magnet, and a lens assembled into the switch between the housing and the outer component. The lens includes a sensor positioned within a cavity of the lens in alignment with the clip magnet to detect the position of the pressure switch dial from a magnetic orientation of the magnet, and circuitry for converting the detected position into an electric signal.

### BRIEF DESCRIPTION OF THE DRAWINGS

The foregoing aspects and many of the attendant advantages of this disclosure will become more readily appreciated and the same will become better understood by reference to the following detailed description when taken in conjunction with the accompanying drawings.

FIGS. 1A and 1B are conceptual, representative views of an exemplary circuit breaker having an enclosure containing a gas, and showing the circuit breaker in a closed and opened position.

FIG. 2 is another conceptual, representative view of the circuit breaker of FIG. 1B having an embodiment of a monitoring unit coupled thereto.

FIG. 3 is a perspective view of a pressure switch.

FIG. 4 is a side elevation view of the pressure switch of FIG. 3.

FIG. 5 is a top view of a dial pointer of the pressure switch of FIG. 3.

FIG. 6 is a top view of the pressure switch of FIG. 3, depicting details of a face plate for visually indicating gas pressure.

FIG. 7A is a perspective view of a clip according to one embodiment of the present disclosure.

FIG. 7B is a perspective view of the clip of FIG. 7A attached to a dial pointer.

FIG. 7C is another perspective view of the clip of FIG. 7A.

FIG. 8 is a top view of the clip of FIG. 7A attached to a dial pointer of the pressure switch of FIG. 3.

FIG. 9 is a perspective view of the clip of FIG. 7A attached to a dial pointer of the pressure switch of FIG. 3.

FIG. 10 is a perspective view of a sensor mount according to one embodiment of the present disclosure.

FIG. 11A is a side, cross-sectional view of the sensor mount of FIG. 10.

FIG. 11B is a top, cross sectional view of the sensor mount of FIG. 10.

FIG. 12 is a schematic view of an apparatus according to the present disclosure coupled to a monitoring system.

FIG. 13 is a top view of an apparatus according to the present disclosure attached to the pressure switch of FIG. 3.

FIG. 14 is a perspective view of an apparatus according to the present disclosure attached to the pressure switch of FIG. 3.

FIG. 15 is a perspective view of a lens according to one embodiment of the present disclosure.

FIGS. 16A-C are, respectively, top, side and bottom plan views of a lens according to one embodiment of the present disclosure.

FIG. 17 is a top plan view of a circuit board according to one embodiment of the present disclosure.

FIG. 18 is a side, cross-sectional view of the lens of FIGS. 16A-C assembled into the pressure switch of FIG. 3.

FIG. 19 is a top view of the assembly of FIG. 18.

FIG. 20 is a perspective view of the lens of FIG. 15 positioned onto the housing of the pressure switch of FIG. 3.

FIG. 21 is a perspective view of the lens of FIG. 15 assembled into the pressure switch of FIG. 3.

FIG. 22 is a schematic view of circuitry for use in any of the lens embodiments disclosed herein.

FIGS. 23A-B are, respectively, side and top plan views of another pressure switch.

FIG. 24 is a perspective view of the pressure switch of FIGS. 23A-B in a fully assembled state and a disassembled state.

FIG. 25 is a top plan view of a lens according to another embodiment of the present disclosure.

FIG. 26 is a side, cross-sectional view of the lens of FIG. 25 assembled into the switch of FIGS. 23A-B.

FIG. 27 is a top plan view of the assembly of FIG. 26.

FIG. 28 is a perspective view of the assembly of FIG. 26.

FIG. 29 is another top plan view of the assembly of FIG. 26.

Corresponding reference characters indicate corresponding parts throughout the several views. Although the drawings represent embodiments of various features and components according to the present disclosure, the drawings are not necessarily to scale and certain features may be exaggerated in order to better illustrate and explain the present disclosure. The exemplification set out herein illustrates embodiments of the invention, and such exemplifications are not to be construed as limiting the scope of the invention in any manner.

### DETAILED DESCRIPTION OF THE DRAWINGS

For the purposes of promoting an understanding of the principles of the disclosure, reference will now be made to the embodiments illustrated in the drawings, which are described below. The embodiments disclosed below are not intended to be exhaustive or limit the disclosure to the precise form disclosed in the following detailed description. Rather, the embodiments are chosen and described so that others skilled in the art may utilize their teachings. It will be understood that no limitation of the scope of the disclosure is thereby intended. The disclosure includes any alterations and further modifications in the illustrated devices and described methods and further applications of the principles of the disclosure which would normally occur to one skilled in the art to which the disclosure relates.

Co-pending U.S. patent application Ser. No. 13/411,011, filed Mar. 2, 2012, entitled “GAS DENSITY MONITORING SYSTEM” (hereinafter, “the Monitoring System Application”), the entire disclosure of which is expressly incorporated herein by reference, discloses a system for monitoring gas levels in high voltage circuit breakers. As described in the Monitoring System Application, a monitoring unit is connected to an SF6 sensor which provides signals representing the density of SF6 gas in a circuit breaker to which the SF6 sensor is connected.

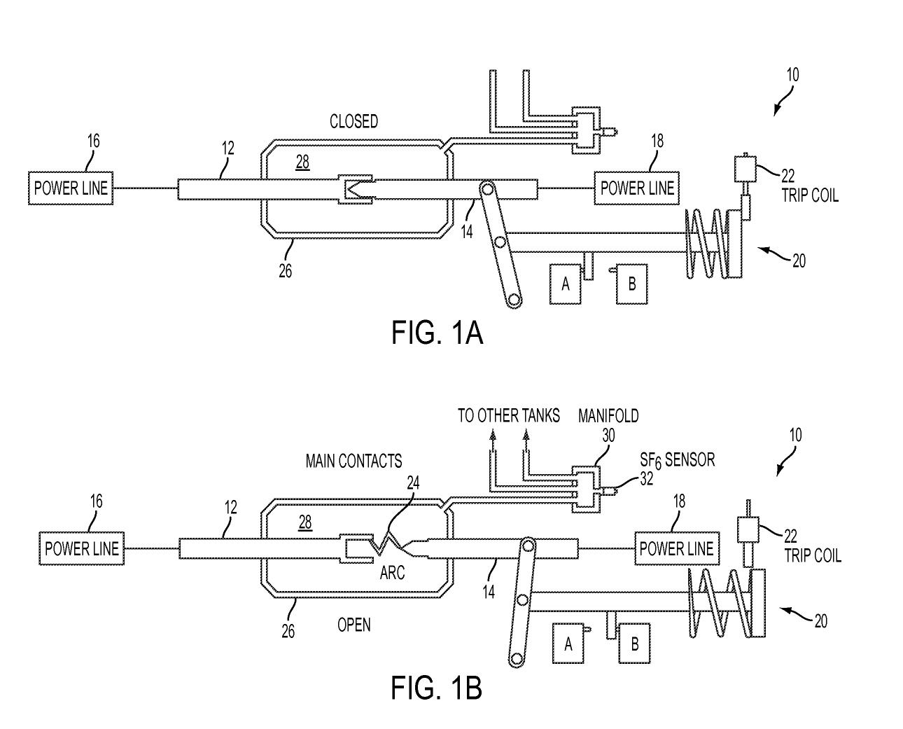

As explained in the Monitoring System Application and referring to FIG. 1A, a conventional circuit breaker 10 includes a first conductive element 12 and a second conductive element 14 which is moveable relative to first conductive element 12 through a plunger system 20. When first conductive element 12 is in physical contact with second conductive element 14, electricity is able to flow between a first power line 16 and a second power line 18. By contrast, when first conductive element 12 is separated from second conductive element 14, electricity generally is unable to flow between the first power line 16 and the second power line 18.

As shown in FIG. 1A, second conductive element 14 is in physical contact with first conductive element 12, hence circuit breaker 10 is in a closed state. As shown in FIG. 1B, second conductive element 14 is separated from first conductive element 12, hence circuit breaker 10 is in an open state. A circuit breaker control (not shown) actuates a trip coil 22 which permits circuit breaker 10 to transition to the open state of FIG. 1B. A closing spring system (not shown) is controlled by the circuit breaker control to transition circuit breaker 10 back to the closed state of FIG. 1A.

As circuit breaker 10 transitions from the closed state of FIG. 1A to the open state of FIG. 1B, an arc 24 between first conductive element 12 and second conductive element 14 is sometimes generated. In order to minimize the occurrence, the intensity, and/or the duration of arc 24, the connection between first conductive element 12 and second conductive element 14 is surrounded by an enclosure 26 filled with a gas 28. An exemplary gas is Sulphur-Hexa-Fluoride (“SF6”) or a mixture including SF6. Other exemplary gases may be used. The presence of the gas 28 as a dielectric reduces the amount of damage experienced by circuit breaker 10 due to arc 24 because gas 28 acts to extinguish the arc 24. An exemplary circuit breaker 10 and enclosure 26 are the Siemens SPS2 circuit breaker (15 kV-245 kV) available from Siemens Power Transmission and Distribution located at 444 Hwy. 49 S in Richland, Miss. 39218 USA.

Enclosure 26 provides a generally sealed volume around the connection between first conductive element 12 and second conductive element 14. Gas 28 in enclosure 26 does, however, over time leak from the interior of enclosure 26 to the exterior of enclosure 26. As shown in FIG. 1B, a manifold 30 is in fluid communication with the interior of enclosure 26 and the interior of other enclosures. Manifold 30 supports a gas sensor 32 and exposes the gas sensor 32 to gas 28 in manifold 30 which is generally at the same pressure and temperature as gas 28 in the interior of enclosure 26.

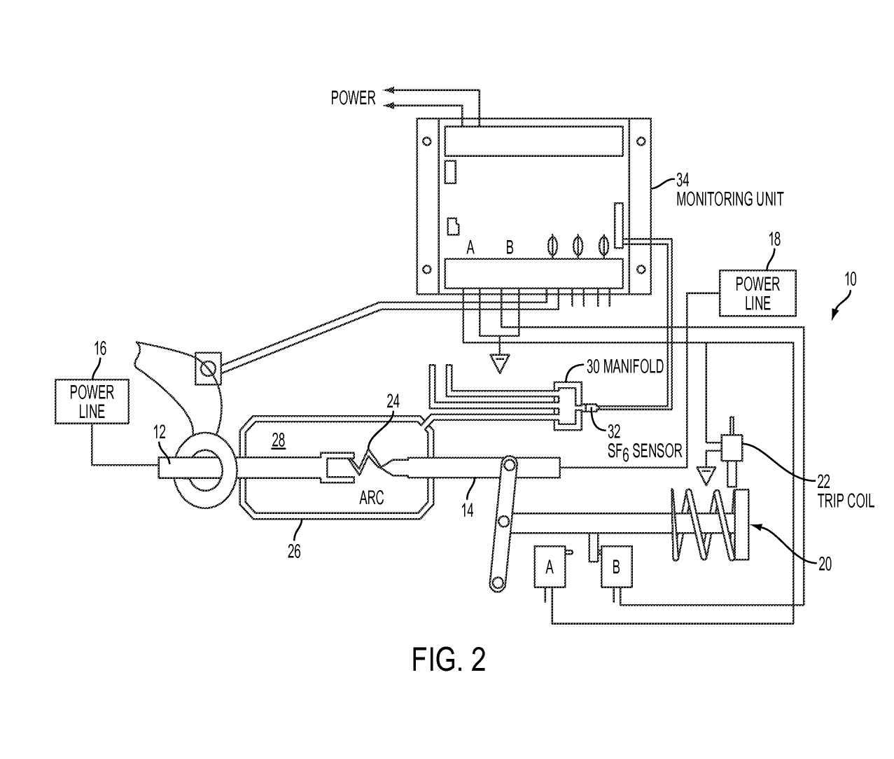

Referring now to FIG. 2, in the system disclosed in the Monitoring System Application, gas sensor 32 is monitored by a monitoring unit 34. Based on the output of gas sensor 32, monitoring unit 34 determines one or more characteristics of gas 28 in enclosure 26. In one embodiment, monitoring system 34 further monitors one or more characteristics of the current flowing between first power line 16 and second power line 18. Monitoring unit 34, based on the one or more characteristics of gas 28 in enclosure 26 determines one or more characteristics about circuit breaker 10. Additional details regarding these characteristics and the operation of an exemplary embodiment of monitoring unit 34 are provided in the Monitoring System Application.

As described above, in order for monitoring unit 34 to determine characteristics about circuit breaker 10, gas sensor 32 must be introduced into the gas plumbing of manifold 30, and electrically connected to monitoring unit 34. The costs associated with the labor required to make the required plumbing modifications and electrical connections may be high. Accordingly, an alternative approach that reduces retrofit installation costs associated with use of monitoring unit 34 is desirable. The present disclosure provides a method and apparatus for providing gas density and/or pressure signals to monitoring unit 34 without requiring a new gas connection to circuit breaker 10 or manifold 30 by converting the mechanical movement of a dial pointer of a fail-safe diaphragm switch coupled to circuit breaker 10 into an electrical gas density and/or pressure signal for use by monitoring unit 34.

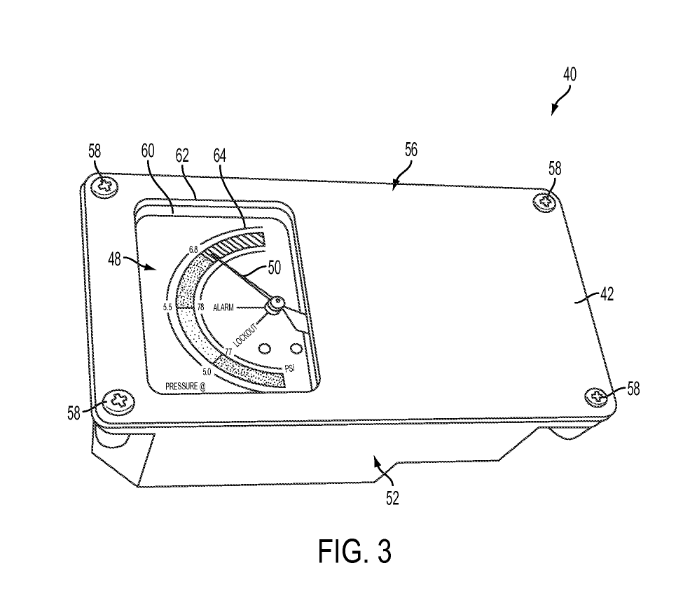

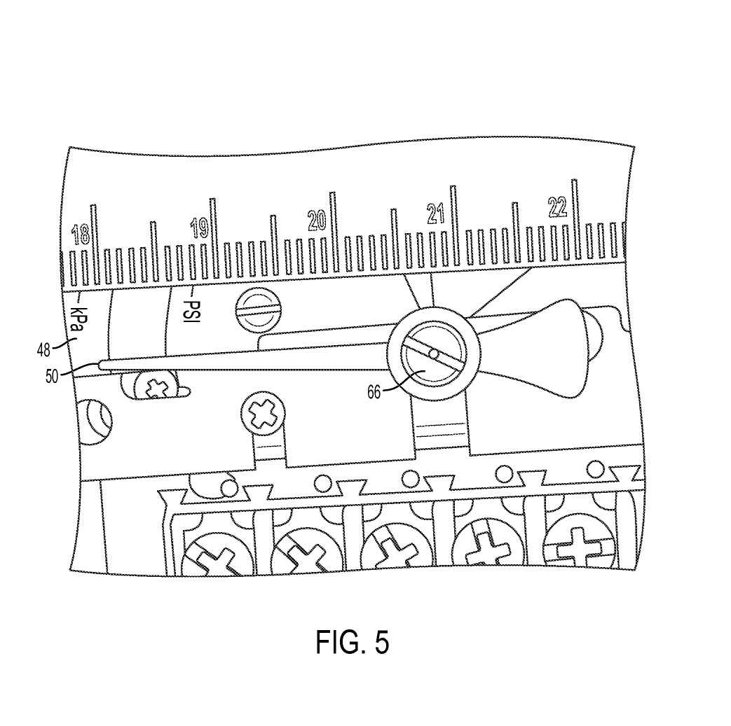

A common, mechanical diaphragm switch used with a large number of high voltage circuit breakers as a fail-safe mechanism is the Solon switch. The most popular Solon switch of this type is the Model 2TC, which is depicted in FIGS. 3-6. As shown, the switch 40 generally includes a housing 42, a gas inlet fitting T, internal, temperature compensated switching and gauge mechanisms 46, a gauge face plate 48, and a movable dial pointer 50. Housing 42 generally includes a body 52, a lens 54, an outer component (in this embodiment, cover plate 56), and four attachment screws 58. Cover plate 56 includes an opening 60 that generally corresponds to the size of gauge face plate 48 and permits viewing of gauge face plate 48 and dial pointer 50. As best shown in FIG. 5, dial pointer 50 is attached to temperature compensated switching and gauge mechanisms 46 by a screw 66. As described below, one component of the apparatus of the present disclosure is attached to dial pointer 50 by clipping on to dial pointer 50 over screw 66.

The Solon Model 2TC is a temperature compensated pressure switch with an integral dial indicator (i.e., dial pointer 50). The gas in circuit breaker 10 is communicated through gas inlet fitting T and exposed to switching and gauge mechanisms 46. The pressure of the gas acts against a calibrated spring mechanism of switching and gauge mechanisms 46 which is adjusted by a bimetallic temperature compensation mechanism of switching and gauge mechanisms 46. As the gas pressure acts against the calibrated spring mechanism, it causes dial pointer 50 to move and actuates two, three or four calibrated micro-switches located at preset points in its travel corresponding to the thresholds described below. The temperature compensation mechanism acts on the spring in varying amounts, depending upon the temperature of the gas. In general, the temperature compensation mechanism applies force to the calibrated spring mechanism in a manner that compensates for pressure increases or decreases due to temperature changes as opposed to gas leaks. In other words, the temperature compensation mechanism allows for the expansion and contraction of the gas over a temperature range by compensating for the change in pressure due to temperature. The pressure reading on dial indicator 50 remains constant over the temperature range, even though the actual pressure of the gas varies as a function of temperature. Typically, the pressure is compensated to 20 degrees Celsius, so that whatever the actual temperature is, the dial indicates what the gas pressure would be at 20 degrees Celsius.

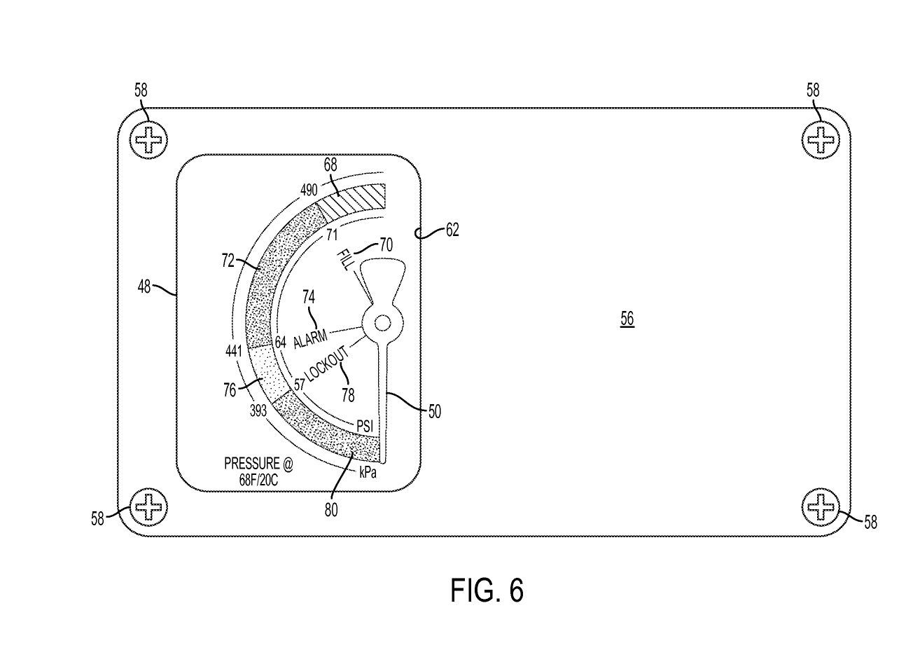

Referring now to FIG. 6, face plate 48 includes four segments corresponding to pressure ranges of SF6 gas measured by switch 40. The over-fill range 68 corresponds to gas pressures above a fill threshold 70, which in this example, is 71 PSI or 490 kPa. Gas pressures in over-fill range 68 indicate an extra high level of SF6 gas present in circuit breaker 10. The normal range 72 corresponds to gas pressures between fill threshold 70 and an alarm threshold 74, which in this example, is 64 PSI or 441 kPa. Gas pressures in normal range 72 indicate a sufficient level of SF6 gas present in circuit breaker 10. The alarm range 76 corresponds to gas pressures between alarm threshold 74 and a lockout threshold 78, which in this example, is 57 PSI or 393 kPa. Gas pressures in alarm range 76 indicate that the gas level in circuit breaker 10 is unacceptably low, requiring prompt addition of gas. The lockout range 80 corresponds to gas pressures below lockout threshold 78. Gas pressures in lockout range 80 cause switch 40 to disable circuit breaker 10. More specifically, when dial pointer 50 reaches lockout threshold 78, a micro-switch of switching and gauge mechanisms 46 (described above) is opened. The micro-switch is wired in series with trip coil 22 of circuit breaker 10 (see FIGS. 1A and 1B), and is normally closed, thereby permitting power to flow to trip coil 22 when circuit breaker 10 needs to be tripped. When the gas pressure within switch 40 is sufficiently low to cause dial pointer 50 to pass below lockout threshold 78, the micro-switch is opened, thereby cutting off power to trip coil 22 and preventing circuit breaker 10 from tripping.

Depending upon the pressure and temperature of the gas as sensed by temperature compensated switching and gauge mechanisms 46, dial pointer 50 is rotated to a measured, temperature compensated pressure within one of over-fill range 68, normal range 72, alarm range 76, or lockout range 80.

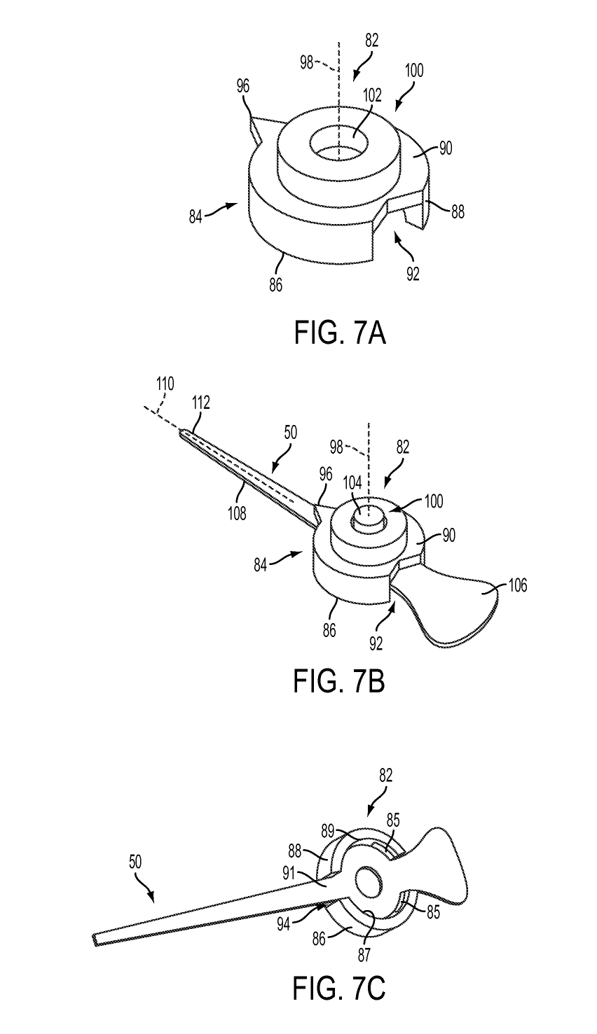

As best shown in FIGS. 7A-C, the first component of an apparatus according to the present disclosure is a magnet clip 82. As shown in FIG. 7A, clip 82 includes a base 84 having a pair of annular walls 86, 88 and an upper surface 90. Annular walls 86, 88 and upper surface 90 together define a first opening 92 and a second opening 94 (FIG. 7C). Upper surface 90 includes a pointer 96 that extends radially out from a central axis 98 of clip 82. Clip 82 further includes an upper ring 100 that extends upwardly from upper surface 90 and is disposed directly over central axis 98. Ring 100 defines a central recess 102 which receives a magnet 104 as shown in FIG. 7B.

Referring now to FIG. 7B, clip 82 is attached to dial pointer 50 by placing base 84 over the center of screw 66 (FIG. 5) such that first opening 92 receives a base 106 of dial pointer 50 and second opening 94 (FIG. 7C) receives a tip 108 of dial pointer 50. As clip 82 is pressed downwardly onto dial pointer 50, clip 82 snaps into engagement with dial pointer 50. More specifically (and referring to FIG. 7C), a plurality of resilient protrusions 85 (only two shown) extend from inner surfaces 87, 89 of annular walls 86, 88, respectively, toward central axis 98. Protrusions 85 are sized such that the distances between the innermost edges of protrusions 85 (i.e., the edges closest to central axis 98) are approximately the same, but slightly smaller, than the diameter of a circular central portion 91 of dial pointer 50. As such, when clip 82 is pressed downwardly onto central portion 91 of dial pointer 50, protrusions 85 compress slightly, then return to their original orientations, thereby hooking under or gripping onto central portion 91 of dial pointer 50. As should be understood by those skilled in the art, other structure may be implemented for attaching clip 82 to dial pointer 50.

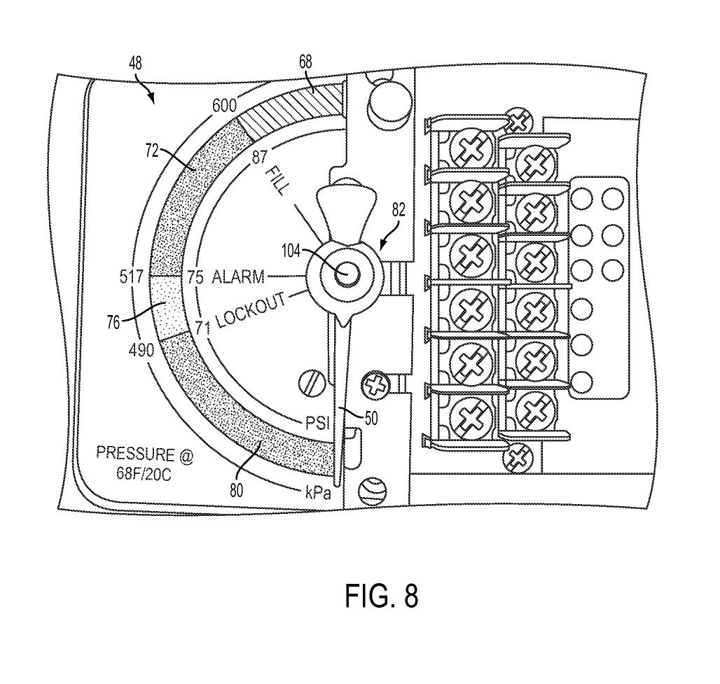

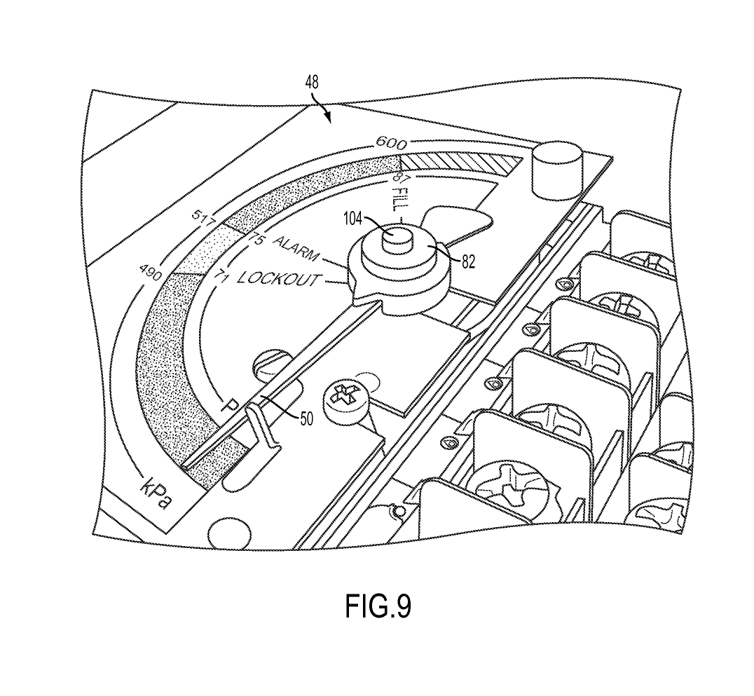

As shown, when installed onto dial pointer 50, clip pointer 96, which corresponds to the north direction of magnet 104, is aligned with a longitudinal axis 110 of dial pointer 50 and aimed toward an end 112 of tip 108. As such, when dial pointer 50 rotates, magnet 104 also rotates about central axis 98 and any deviation from the north direction can be directly translated into the position of dial pointer 50 on face plate 48. In this manner, the angular location of magnet 104 can be mapped to the locations of over-fill range 68, fill threshold 70, normal range 72, alarm threshold 74, alarm range 76, lockout threshold 78 and lockout range 80 on face plate 48. FIGS. 8 and 9 show clip 82 attached to dial pointer 50.

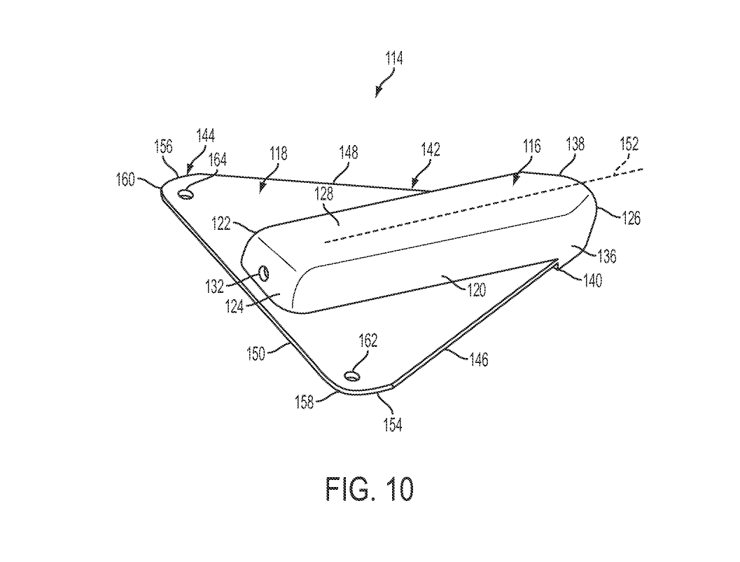

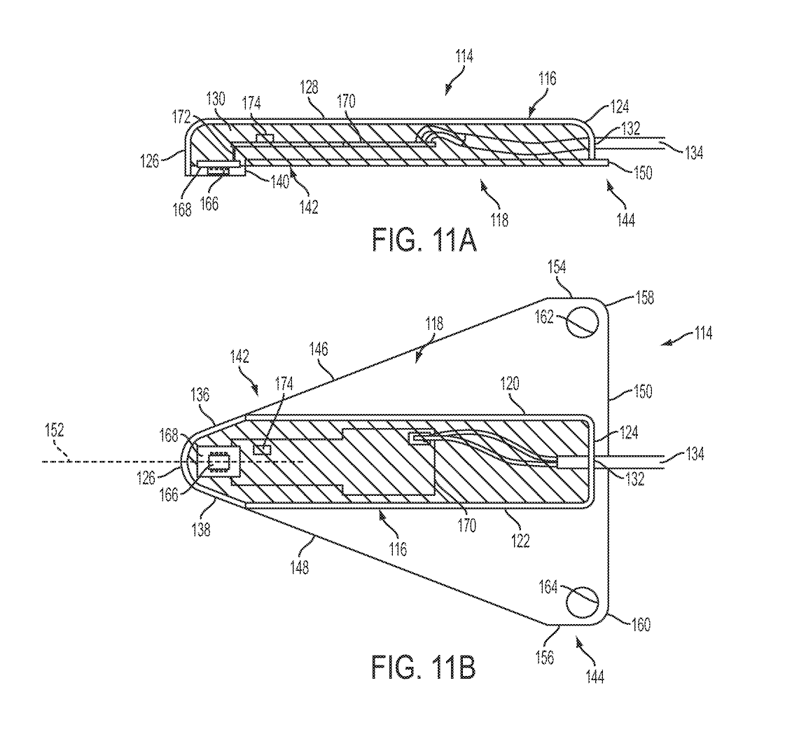

Referring now to FIGS. 10 and 11A-B, the second component of an apparatus according to the present disclosure is a sensor mount 114. Sensor mount 114 generally includes a housing 116 and a mounting plate 118. Housing 116 includes side walls 120, 122, rear wall 124, forward wall 126 and top wall 128. Side walls 120, 122 and rear wall 124 are attached to or integrally formed with mounting plate 118 to define an interior space 130 which is occupied by sensor electronics as is further described below. Rear wall 124 includes an opening 132 through which extends a cable 134 that provides position signals to monitoring unit 34 in the manner described below. As best shown in FIG. 11A, forward wall 126 and a forward portion 136, 138 of side walls 120, 122, respectively, extend downwardly below the plane of mounting plate 118 to form a shoulder 140.

Mounting plate 118 includes a forward end 142 and a rear end 144. In one embodiment as shown in the figures, rear end 144 tapers toward forward end 142 along edges 146, 148 which conform to the angle defined by the forward portions 136, 138 of side walls 120, 122. Rear end 144 includes a rear edge 150 that is substantially perpendicular to a longitudinal axis 152 of sensor mount 114, side edges 154, 156 that are substantially perpendicular to rear edge 150 and joined to rear edge 150 by chamfers 158, 160, respectively. Mounting plate 118 further includes openings 162, 164 which are formed adjacent chamfers 158, 160, respectively, and used to mount sensor mount 114 to switch 40 in the manner described below.

Referring now to FIGS. 11A-B, the sensor electronics are mounted within interior space 130 using any of a variety of conventional mounting techniques. In general, the sensor electronics include a magnetic position encoder chip 166 mounted to a support 168 and electrically connected to an encoder interface board 170 by wires 172. The output of board 170 is connected to cable 134, over which all of the sensor electronics receive DC power from monitoring unit 34. A thermistor 174 is also electrically connected to board 170.

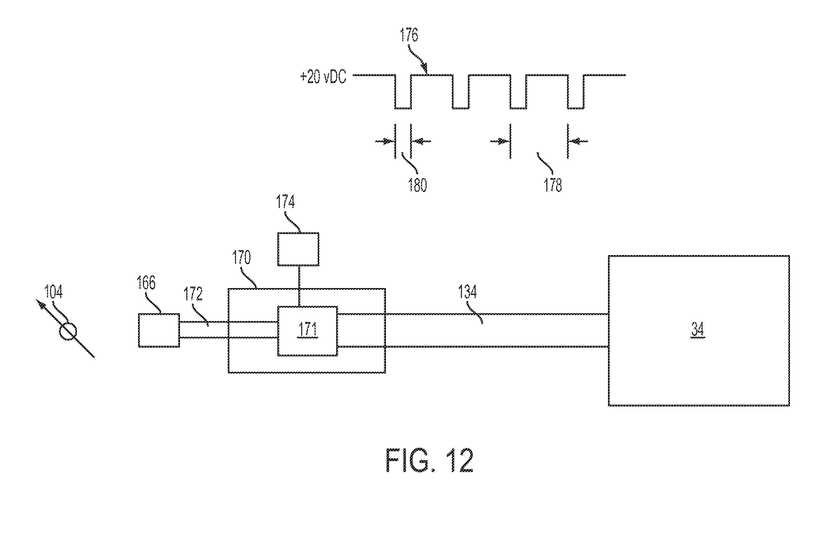

FIG. 12 is a schematic view of the sensor electronics of sensor mount 114. As shown, magnetic position encoder chip 166 is located in proximity to magnet 104 of clip 82. Chip 166 is connected by wires 172 to encoder a microprocessor 171 mounted to interface board 170. Chip 166 provides a proportional signal to microprocessor 171 representing the angular orientation of magnet 104 on dial pointer 50. Additionally, thermistor 174 provides a signal representing ambient temperature to the microprocessor 171. Microprocessor 171 then processes the temperature signal and the proportional signal from chip 166 and outputs a pulse width modulated output signal 176 to monitoring unit 34 that is encoded with temperature information and position (or angle) information regarding the position of magnet 104 (and therefore dial pointer 50) relative to north. The period of each cycle (represented by numeral 178) corresponds to the position of magnet 104 relative to north, and the duration of each negative going pulse (represented by numeral 180) corresponds to the temperature. Monitoring unit 34 decodes this signal to determine the position of dial pointer 50 and the temperature of the gas inside circuit breaker 10.

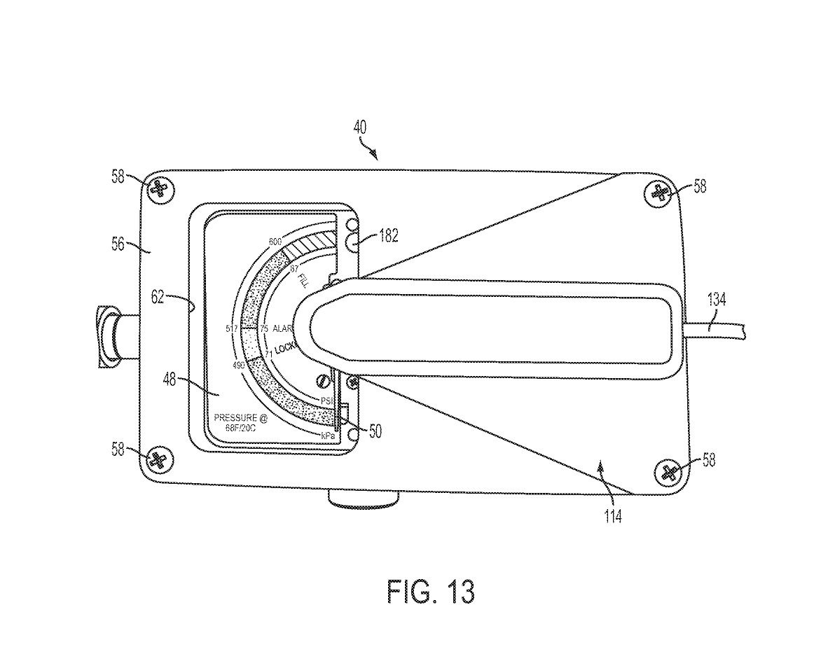

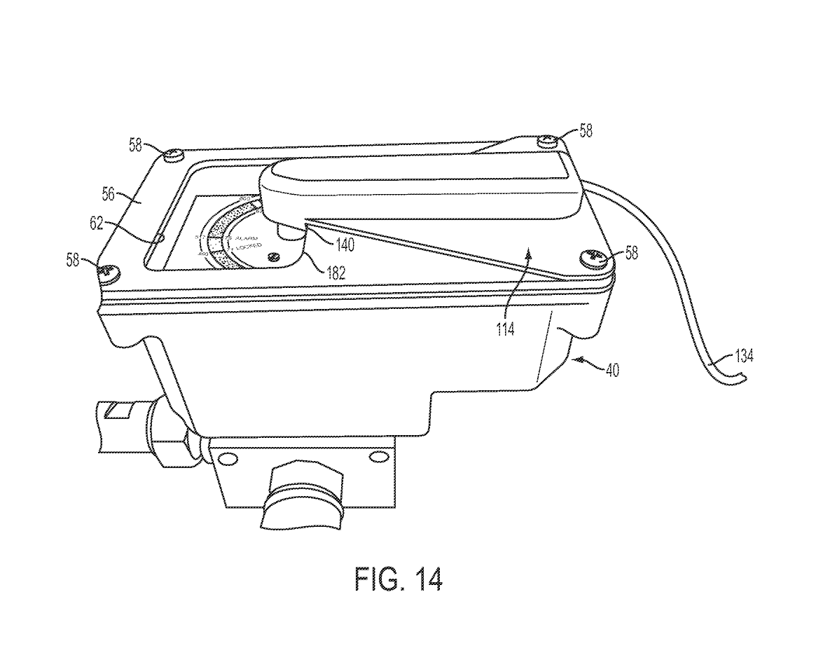

Referring to FIGS. 13 and 14, the installation process for clip 82 and sensor mount 114 is as described below. The installer first removes screws 58 from switch 40. Cover plate 56 and lens 54 are then removed to expose dial pointer 50. Clip 82 is installed on dial pointer 50 in the manner described above. Cover plate 56 and lens 54 are then placed back on housing 42 and the left screws 58 (i.e., the screws 58 closest to face plate 48) are finger tightened to hold cover plate 56 in place. Sensor mount 114 is then place onto cover plate 56 such that shoulder 140 is aligned with edge 182 of opening 62 of cover plate 56 and openings 162, 164 of mounting plate 118 align with the openings in housing 40 for receiving the right screws 58. Right screws 58 are then placed through openings 162, 164 and corresponding openings in cover plate 56 and, along with left screws 58, are tightened in place. Finally, cable 134 is connected to monitoring unit 34.

When installed in this manner, magnetic position encoder chip 166 is fixed in close proximity and directly above magnet 104 of clip 82. As such, sensor mount 114 is able to sense the position of dial pointer 50 in the manner described above.

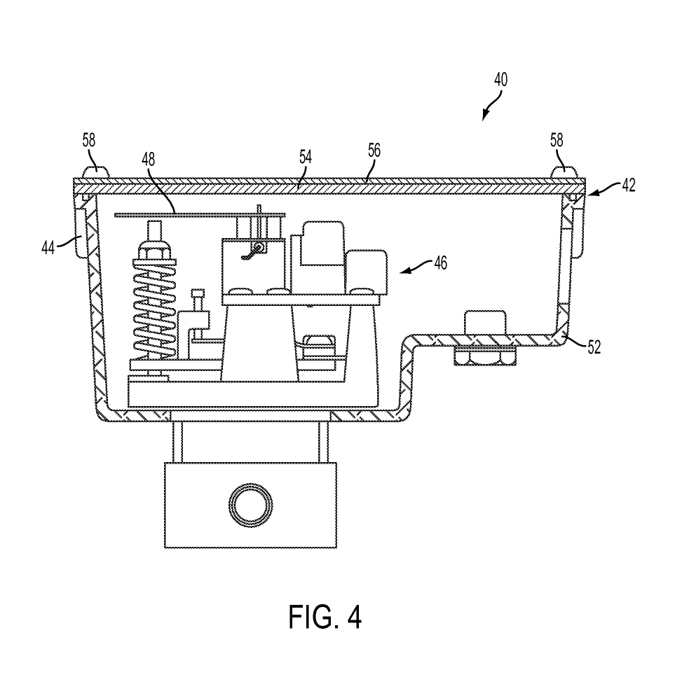

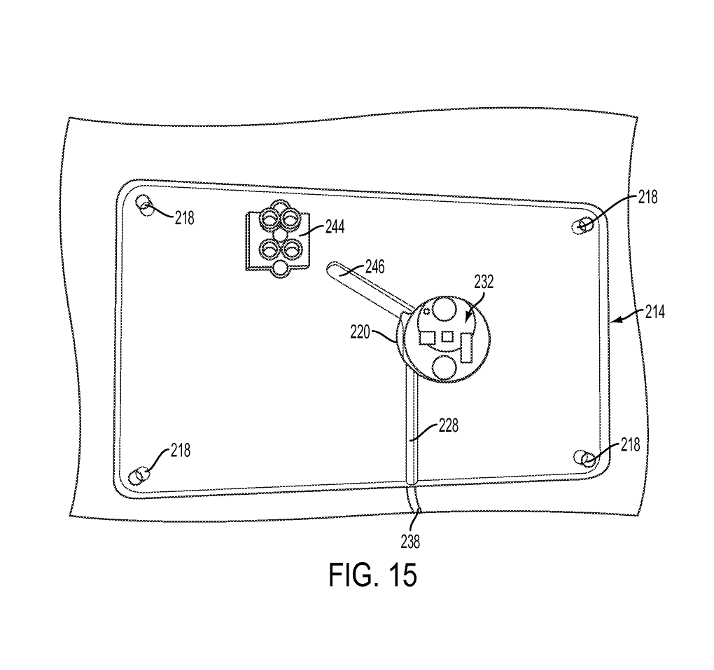

Referring now to FIG. 15, a second component of an apparatus according to the present disclosure is lens 214, which is configured for use as a substitute for lens 54 of switch 40 (FIG. 4). Lens 214 may be configured as a retrofit lens or an OEM lens, as is further described below. Lens 214 of FIG. 10 is depicted as including the features of both the retrofit configuration and the OEM configuration. While lens 214 may be provided in this combined configuration, ordinarily only the features of one or the other configuration are included.

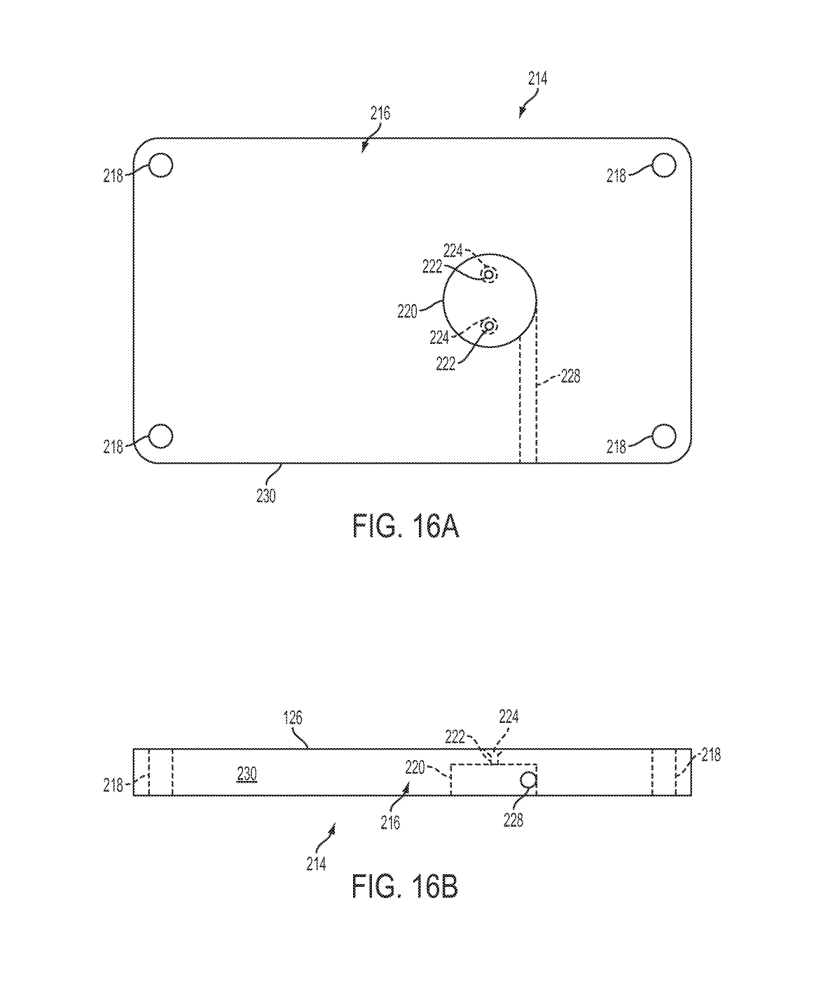

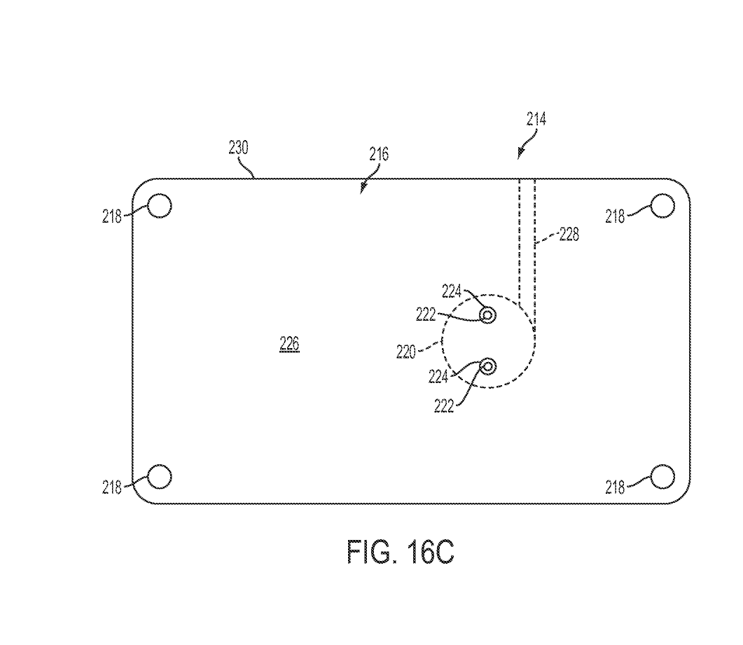

As best shown in FIGS. 16A-C, which depict a bottom view, side view, and top view of lens 214, respectively, in a retrofit configuration, lens 214 includes a body 216 having a generally rectangular shape corresponding to the dimensions of housing 42 of switch 40, and including a plurality of openings 218 located to align with the openings in housing 42 that receive attachment screws 58 of switch 40. Body 216 also includes a cavity 220 configured to receive a circuit board (described below), and a pair of through holes 222, each having a chamfer 224 and extending from an upper surface 226 of body 216 to cavity 220. Finally, body 216 also includes a wiring tunnel 228 which extends laterally through the thickness of body 216 from cavity 222 to an edge 230 of body 216.

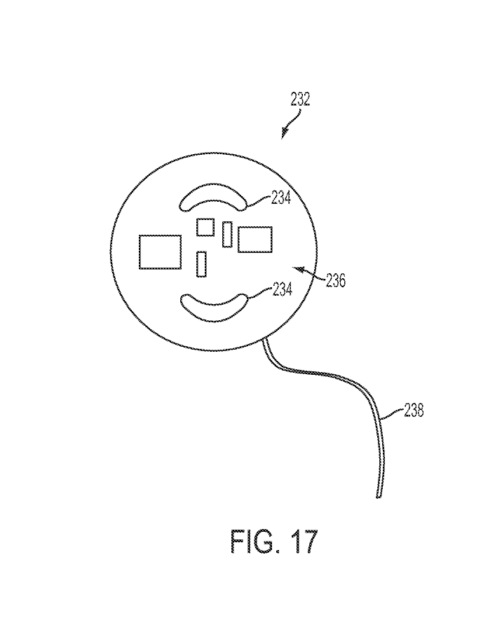

Referring now to FIG. 17, lens 214 further includes a circuit board 232 which is configured to be mounted within cavity 222 as described below. Circuit board 232 includes a pair of calibration slots 234, electrical circuitry 236 (as further described below), and wires 238 connected to electrical circuitry 236. Circuit board 232 may be a single or multi-layer circuit board having mounting locations for integrated circuits and/or passive components, traces interconnecting the components mounted on circuit board 232, and I/O locations for connecting wires 238.

Circuit board 232 is mounted to body 216 by routing wires 238 into cavity 220, through wiring tunnel 228 and out of edge 230 of body 216, and placing circuit board 232 into cavity 220 such that calibration slots 234 align with through holes 222. A pair of screws (not shown) are then placed through holes 222 and slots 234 such that the heads of the screws rest in chamfers 224. A pair of washers (not shown) and nuts (not shown) are then threaded onto the screws and slightly tightened to hold circuit board 232 in place within cavity.

As is further described below, electrical circuitry 236 on circuit board 232 includes a magnetic angle sensor, which is positioned over magnet 104 of clip 82 (FIGS. 7A-C). In this manner, the angle sensor senses the position of dial pointer 50 of switch 40. Thus, the relative position of the circuit board 232 (and therefore the angle sensor) and magnet 104 directly affects the output of electronic circuitry 236. Accordingly, calibration slots 234 permit some rotation of circuit board 232 on the mounting screws to permit adjustments in the position of circuit board 232 in cavity 220. When the final orientation of circuit board 232 is determined, the nuts are fully tightened onto the screws extending through body 216 and circuit board 232, thereby securely mounting circuit board 232 in place. Finally, cavity 220 with circuit board 232 mounted therein is filled with a suitable potting compound such as epoxy, thereby sealing circuit board 232 within cavity 220.

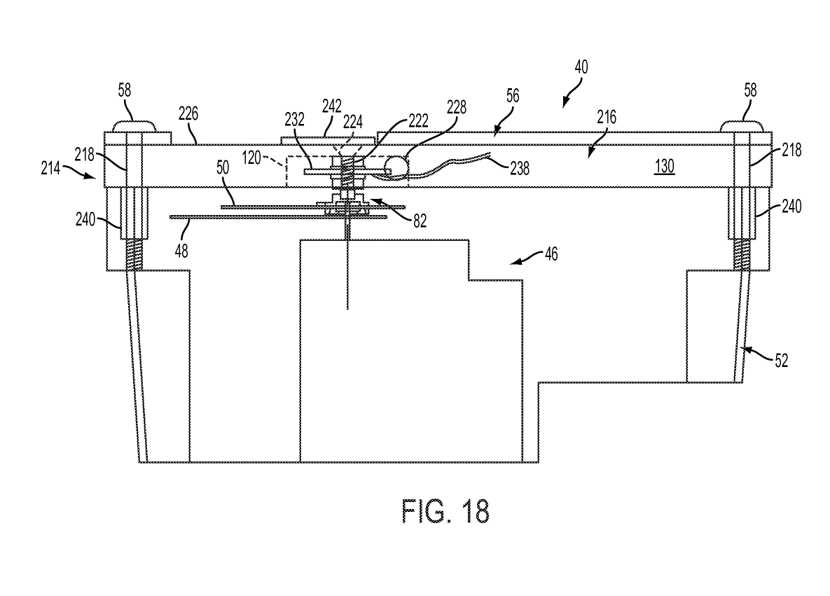

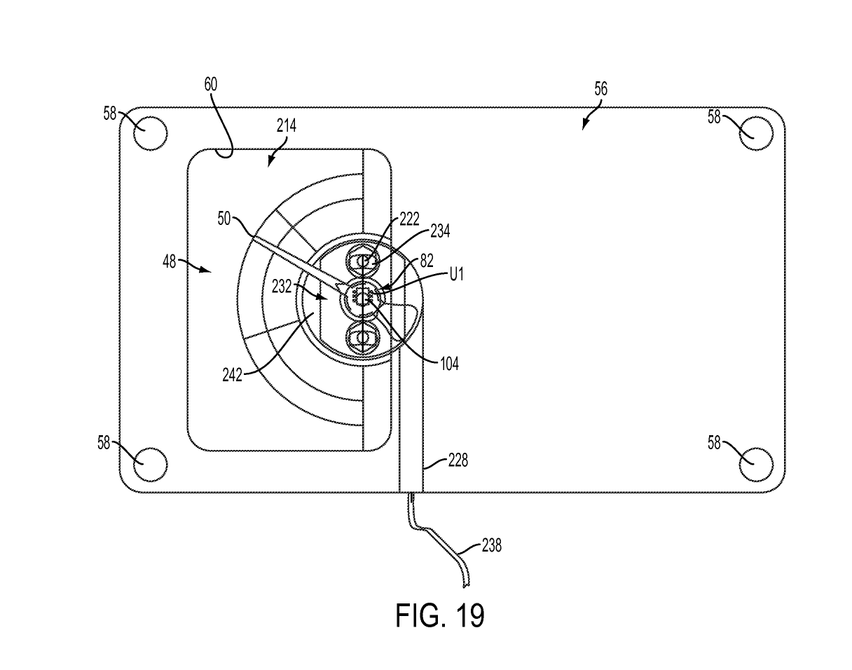

Referring now to FIGS. 18 and 19, lens 214 is shown assembled into switch 40. Lens 214 is not mounted to body 52 of switch 40, but rather is provided as a replacement component (i.e., to replace the existing lens 54 of FIG. 4). This requires some disassembly of switch 40. In particular, attachment screws 58 are removed from switch 40. Next, cover plate 56 is removed to permit access to existing lens 54. Then, lens 54 is removed to expose dial pointer 50. Clip 82 (with magnet 104) is installed on dial pointer 50 in the manner described above. Lens 214 is then placed onto body 52 such that openings 218 of lens 214 align with the openings 240 in body 52. As shown in the figures, this locates the angle sensor of circuit board 232 in close proximity to and directly above magnet 104 of clip 82. Cover plate 56 is then placed onto lens 214, and attachment screws 58 are inserted through cover plate 56 and lens 214, and tightened into openings 240. Finally, wires 238 which extend out of wiring tunnel 228 are connected to monitoring unit 34. It should also be noted that FIG. 13 shows a badge 242 or label affixed to surface 226 of lens 214. Badge 242 conceals circuit board 232 and the mounting hardware, but permits viewing of pointer 50 and face plate 48. In FIG. 19, badge 242 is outlined.

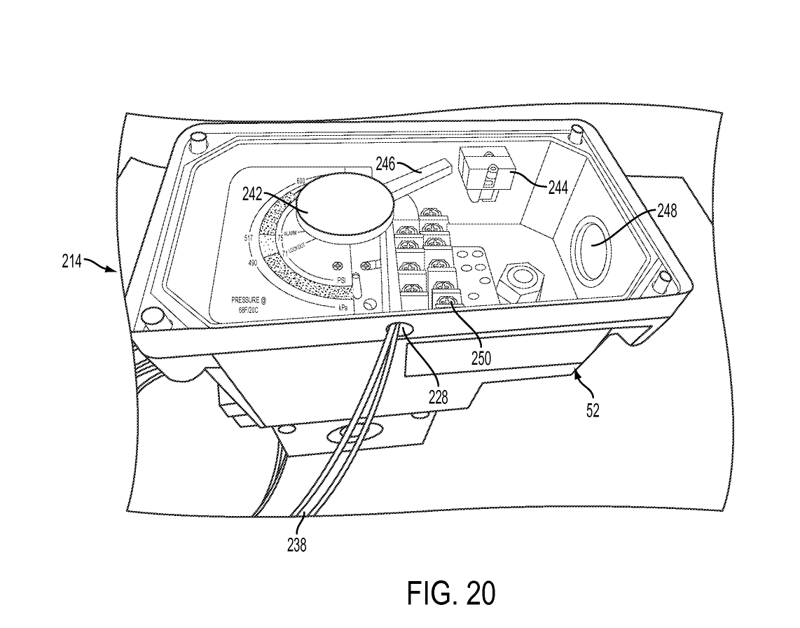

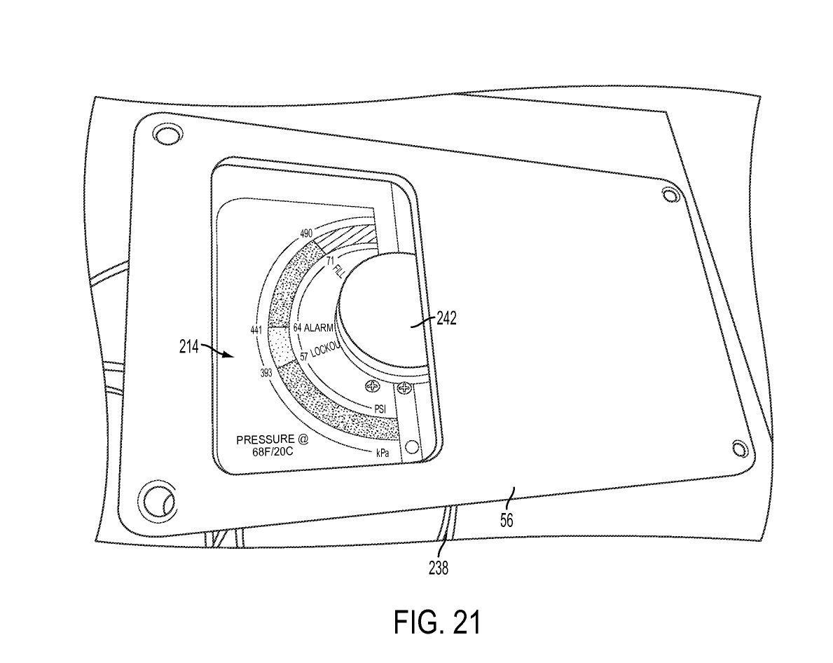

FIG. 20 is a photograph of the lens 214 of FIG. 10 positioned on body 52 of switch 40. While lens 214 also includes features of an OEM configuration (described below), it can be seen that wires 238 extend out of wire tunnel 228 from circuit board 232 (not shown), which is covered by badge 242. FIG. 21 shows the same lens 214 after cover plate 56 of switch 40 has been placed onto lens 214.

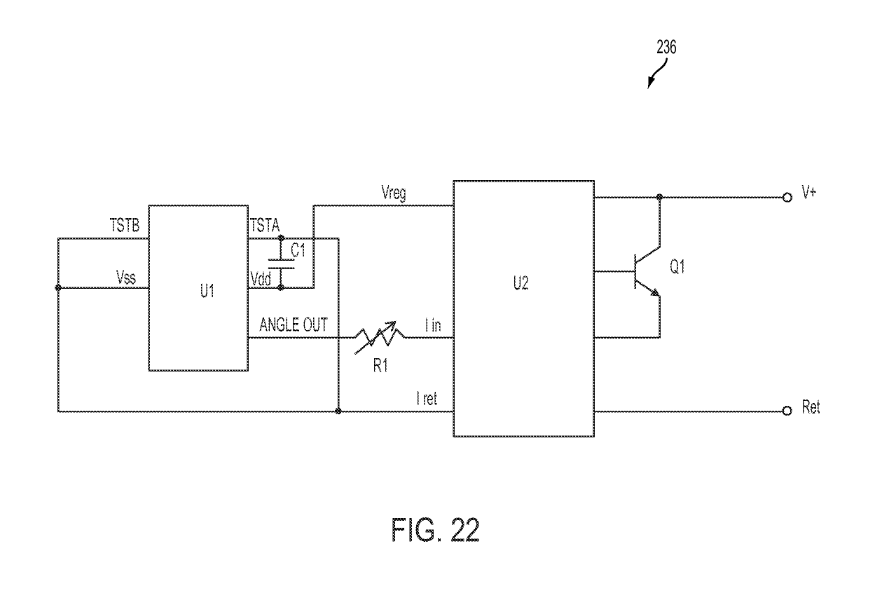

FIG. 22 is a schematic of electrical circuitry 236. As will be apparent to those skilled in the art, many different circuits may be used to provide either an analog or digital output to monitoring unit 34 representing the pressure of SF6 being indicated by dial pointer 50. In general, a sensor is needed to sense the angular position of dial pointer 50 (by sensing the magnetic orientation of magnet 104), and some other circuitry is needed to provide an output signal representing the angular position. FIG. 22 simply depicts one embodiment of a suitable circuit for use in this application.

Electrical circuitry 236 includes U1, U2, C1, R1 and Q1. U1 is a rotational, non-contact angle sensor such as the EM-3242 manufactured by Asahi Kasei Microdevices. U1 (also shown in FIG. 19) includes at least one Hall Element which detects changes in magnetic field, in this case resulting from rotation of magnet 104 with dial pointer 50. U2 is a 4-20 mA current loop transmitter such as the XTR116 manufactured by Burr-Brown Products. C1 is a decoupling capacitor (e.g., 0.1 uF) between the supply voltage Vdd (i.e., Vreg from U2) and the return line. R1 (e.g., 20 KΩ) is provided to generate a current input to U2 that corresponds to the voltage output of U1 representing the sensed angle of magnet 104. Q1 (e.g., an MPSA27 Darlington NPN transistor manufactured by Motorola) is provided to conduct the majority of the full scale output current in the loop.

In general, V+ is carried by one of wires 238 to U2 from monitoring unit 34, where it is connected to the positive side of a 20V supply, the negative side of which is connected, through a load resistor to Ret (also connected to U2 by one of wires 238). V+ is used by an on-chip 5 volt regulator of U2 to provide Vreg, which powers U1. As the output voltage of U1 (Angle Out) changes with changes in orientation of magnet 104 (as sensed by U1), the current flow at Iin to U2 changes accordingly. U2 uses this current input to vary the current flow through the loop formed between U2 and monitoring unit 34 in a manner that indicates the angle of magnet 104. As such, monitoring unit 34 may use the current value (i.e., between approximately 9 and 20 mA, given the current consumption by U1) to determine the angular position of magnet 104, and therefore the position of dial indicator 50.

Turning now to the OEM configuration of lens 214, as shown in FIG. 15, lens 214 may alternatively be configured with a terminal block 244 attached by any of a variety of attachment techniques to the lower side of body 216, and a channel 246 extending along the lower side of body 216 between cavity 220 and terminal block 244. In the OEM configuration, wiring tunnel 228 is omitted. Otherwise, lens 214 and circuit board 238 are identical to the retrofit configuration described above. When circuit board 232 is installed in cavity 220 in the manner described above, wires 238, which are connected to terminal block 244, are routed through channel 246. When cavity 220 is filled with potting compound, channel 246 is also filled.

As best shown in FIG. 20, when in the OEM configuration, terminal block 244 of lens 214 faces into housing body 52 when lens 214 is installed as part of switch 40. In this manner, wires 238 may be routed from an OEM cable connected to monitoring unit 34 that extends into body 52 through opening 248 for connection to terminal block 250 of switch 40.

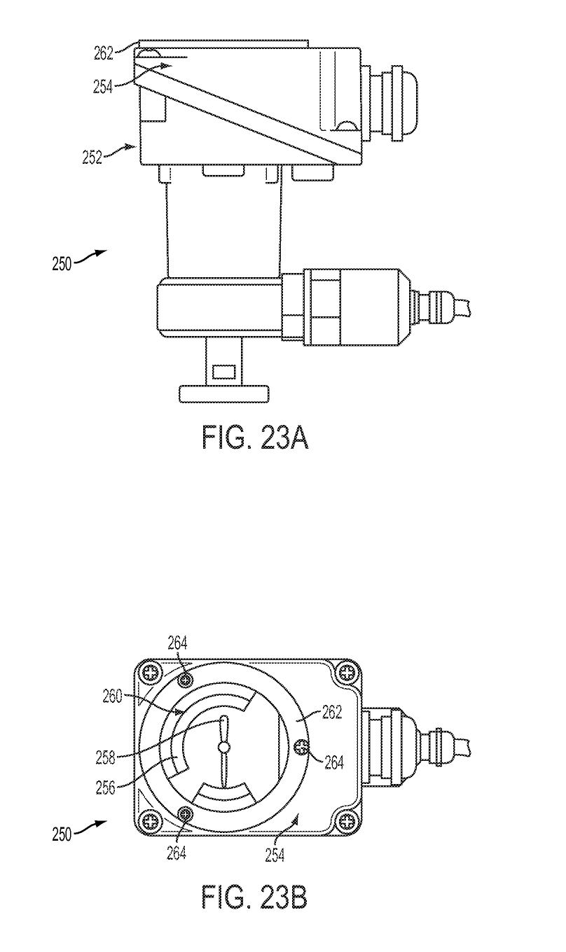

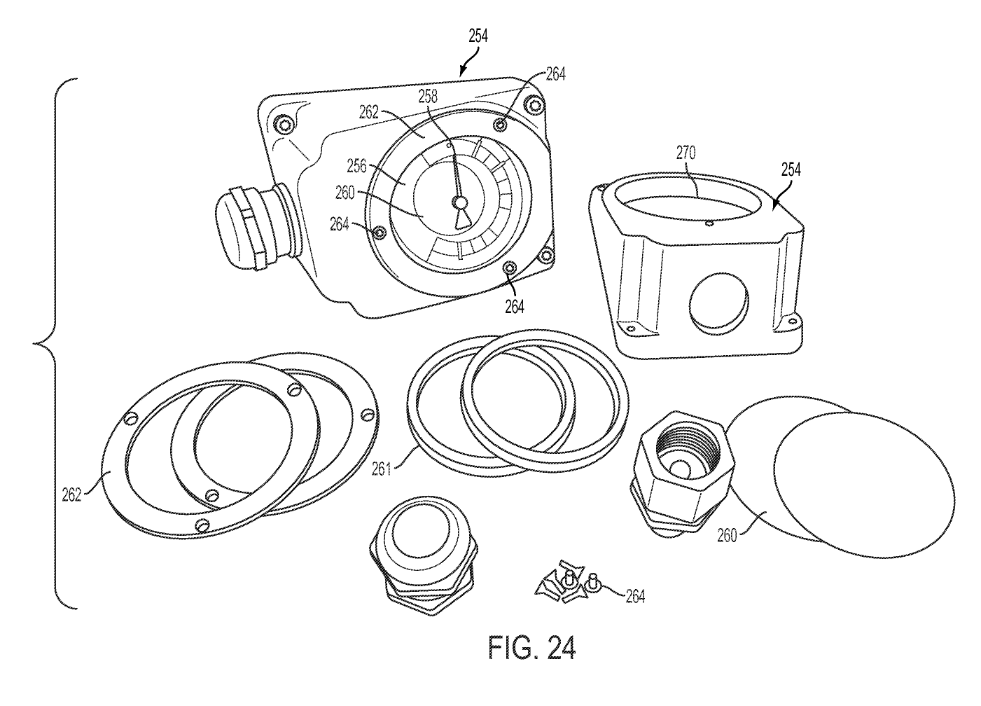

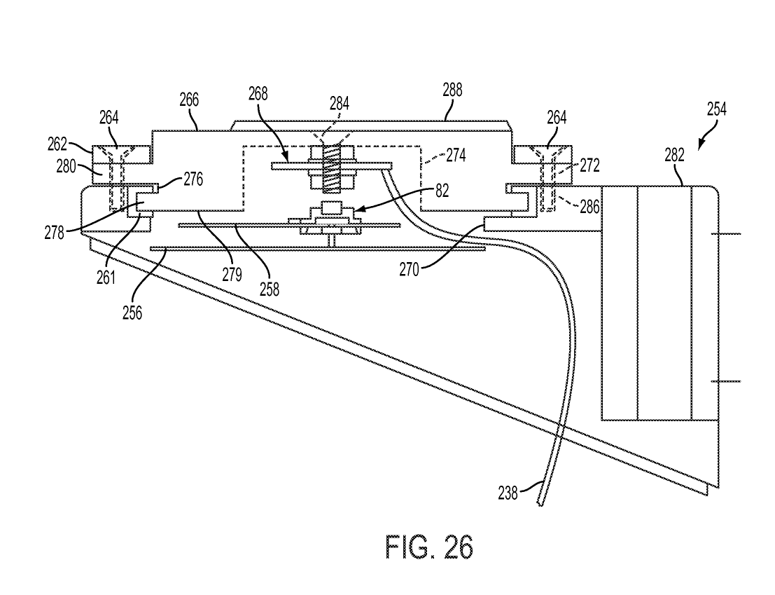

In another embodiment of the present disclosure, the lens component of the present apparatus (i.e., component 214 described above) is configured as an OEM lens for use with an Electronsystem switch such as the switch 250 shown in FIGS. 23A-B. The functionality of switch 250 is, for purposes of the present disclosure, the same as switch 40. The mechanical configuration, however, is different. Switch 250 includes a lower housing 252 and an upper housing 254. As shown in the figures, a face plate 256 is positioned within upper housing 254 and includes a dial pointer 258 for indicating gas pressure in the manner described above with reference to switch 40. A lens 260 is mounted to upper housing 254 and held in place by a rubber gasket 261 (FIGS. 24 and 26) and an outer component of switch 250 (in this embodiment, retaining ring 262). As is further described below, three screws 264 extend through retaining ring 262 and lens 260 into openings 286 (FIG. 26) formed in upper housing 254 to secure lens 260 and retaining ring 262 to upper housing 254.

FIG. 24 show upper housing 254 fully assembled onto lower housing 252 (upper left hand corner of the figure), and disassembled (the remainder of the figure).

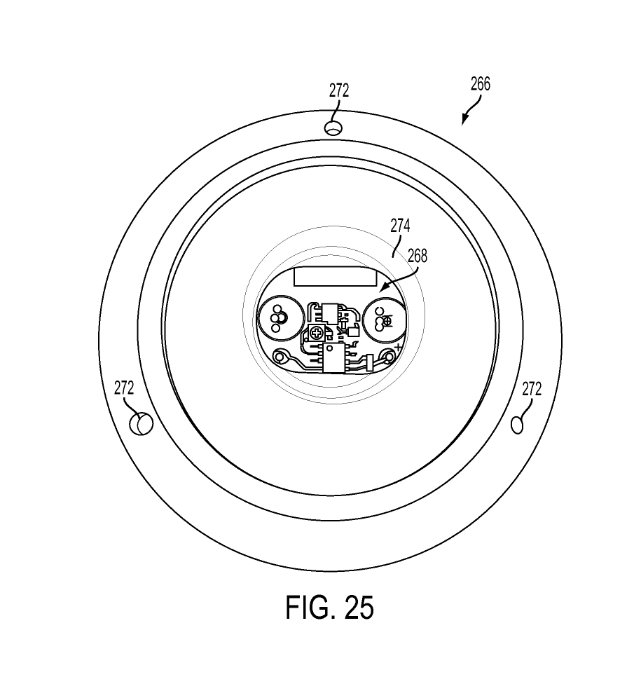

Referring now to FIG. 25, a replacement lens 266 is shown with a circuit board 268 according to the present disclosure attached. Lens 266 is generally circular in shape to correspond to the opening 270 (FIG. 24) in upper housing 254, and includes openings 272 which are spaced and oriented to align with the openings 286 in upper housing 254 for receiving screws 264. Lens 266 further includes a central cavity 274 for receiving circuit board 268. Circuit board 268 may be of the same configuration as circuit board 232 described above.

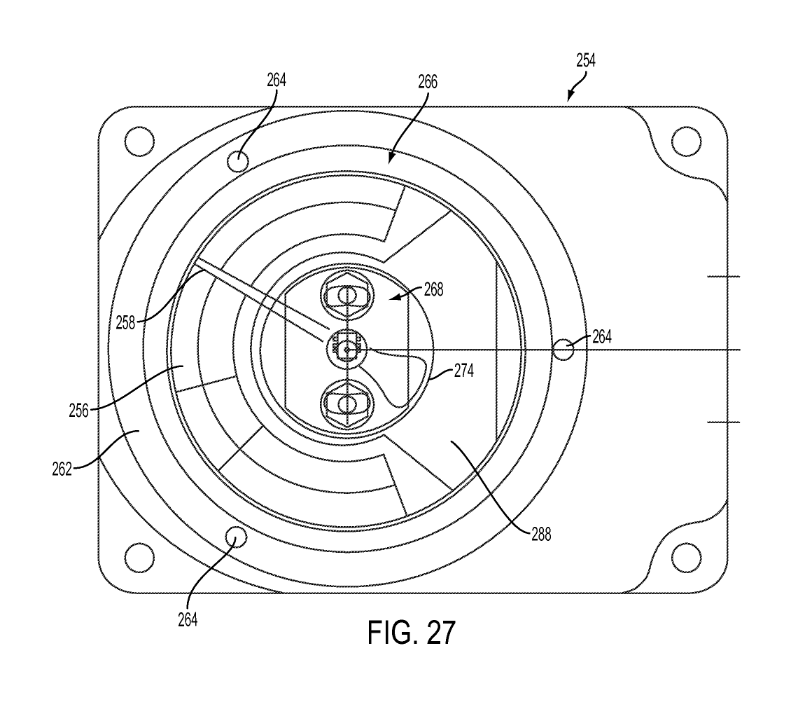

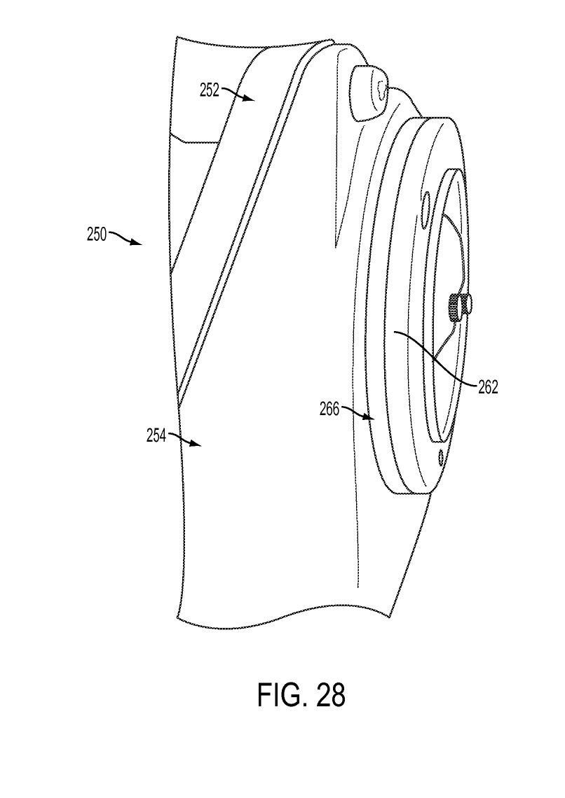

FIGS. 26 and 27 depict lens 266 integrated as an OEM component of switch 250 and clip 82 mounted to dial pointer 258 of switch 250. As shown, lens 266 includes an annular groove 276 which forms an annular flange 278 at the lower surface 279 of lens 266. Gasket 261 of switch 250 has a C-shaped cross-section, and fits onto annular flange 278. Lens 266 further includes a second annular flange 280 which overlays the upper surface 282 of upper housing 254 when lens 266 is installed. Openings 272 of lens 266 extend through second annular flange 280. Finally, lens 266 also includes a pair of chamfers 284 which receive the heads of screws used to mount circuit board 268 within cavity 274 in the manner described above. It should be noted that once installed in cavity 274 and properly oriented as described above, circuit board 268 is potted in place using a potting compound such as epoxy.

Like lens 214 described above, lens 266 is not mounted to upper housing 254 of switch 250, but rather is provided as an integral component (i.e., a replacement for existing lens 260). When switch 250 is assembled, lens 266 (instead of lens 260) is assembled as part of switch 250. In particular, circuit board 268 is mounted within cavity 274 of lens 266 and gasket 261 is installed onto annular flange 278 of lens 266. Clip 82 (and magnet 104) is installed onto dial pointer 258 in the manner described above with reference to dial pointer 50 of switch 40. Wires 238 from circuit board 268 are routed through opening 270 of upper housing 254 and around face plate 256, and are connected to a terminal block (not shown) mounted in lower housing 252 of switch 250. In this manner, wires 238 may be connected to an OEM cable connected to monitoring unit 34 and extending into lower housing 252.

Next, lens 266 is placed into opening 270 of upper housing 254 such that openings 272 in second annular flange 280 align with openings 286 in upper housing 254. Retaining ring 262 is then placed onto second annular flange 280 and screws 264 are passed through retaining ring 262 and second annular flange 280, and tightened into openings 286 of upper housing 254, thereby compressing gasket 261 and securing lens 266 in place. A badge 288 may be attached to lens 266 (as shown in FIG. 26) to cover circuit board 268, but still permit viewing of dial pointer 258 and face plate 256 when switch 250 is in use.

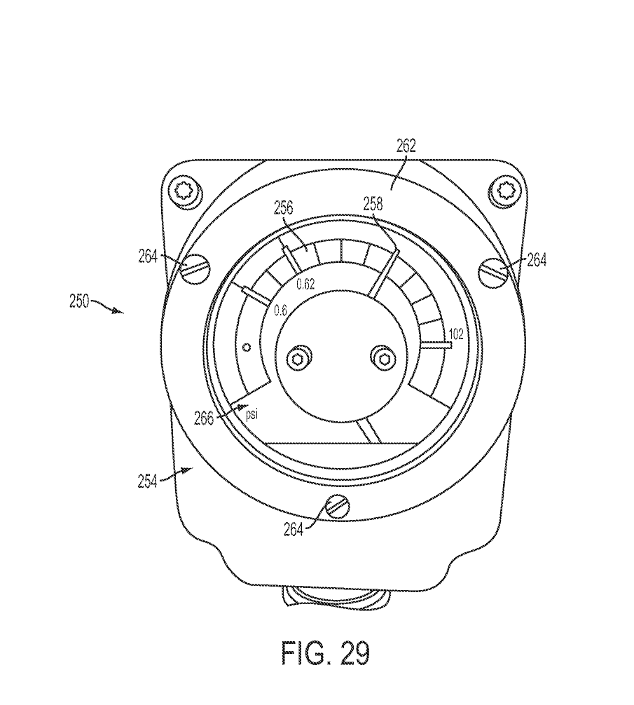

FIGS. 28 and 29 show switch 250 in a fully assembled state including lens 266 (without badge 288).

An exemplary method of the present disclosure of monitoring a circuit breaker is provided. The circuit breaker including a first conductive element electrically coupled to a first power line and a second conductive element electrically coupled to a second power line. A connection of the first conductive element and the second conductive element being positioned in a housing including an arc quenching fluid. At least one characteristic of the arc quenching fluid being monitored by a pressure switch. The second conductive element being movable relative to the first conductive element thereby providing a closed state of the circuit breaker when the first conductive element is in contact with the second conductive element and an open state of the circuit breaker when the first conductive element is spaced apart from the second conductive element. The method comprising the step of monitoring at least one characteristic of the arc quenching fluid by monitoring an angular orientation of a dial pointer of the pressure switch with a non-contact sensor. In one example, the method further comprises the step of monitoring at least one characteristic of the current flowing between the first power line and the second power line.

In a variation thereof, the step of monitoring at least one characteristic of the arc quenching fluid by monitoring a dial pointer of the pressure switch with the non-contact sensor includes the steps of coupling a magnet to the dial pointer, the magnet rotating with the dial pointer; and positioning the non-contact sensor in proximity to the magnet, but spaced apart from the magnet. The non-contact sensor monitoring an angular orientation of the magnet which is indicative of the angular orientation of the dial pointer.

In a further variation thereof, the pressure switch includes a face plate and a lens. The dial pointer is positioned between the face plate and the lens. The non-contact sensor is positioned between an outer surface of the lens and the dial pointer. In a refinement thereof, the steps of monitoring at least one characteristic of the current flowing between the first power line and the second power line; and monitoring at least one characteristic of the arc quenching fluid are performed by a monitoring unit separate from the pressure switch. Further, the method further comprises the step of receiving with the monitoring unit an indication of the angular orientation of the dial pointer.

In another variation thereof, the pressure switch includes a face plate and a lens. The dial pointer is positioned between the face plate and the lens. The non-contact sensor is positioned within a cavity of the lens and in alignment with the magnet. In a refinement thereof, the lens includes a terminal block and the method further includes the step of electrically coupling the non-contact sensor to the terminal block. In a further refinement thereof, the steps of monitoring at least one characteristic of the current flowing between the first power line and the second power line; and monitoring at least one characteristic of the arc quenching fluid are performed by a monitoring unit separate from the pressure switch. The monitoring unit being electrically coupled to the non-contact sensor through the terminal block.

In still another variation thereof, the pressure switch includes a face plate and a lens and the method further comprises the steps of removing the lens of the pressure switch; and assembling a replacement lens to the pressure switch. The replacement lens including the non-contact sensor positioned within a cavity of the lens and in alignment with the magnet. In a refinement thereof, the pressure switch includes an outer component and the method further comprises the step of removing the outer component of the pressure switch. Further, the step of assembling the replacement lens to the pressure switch includes the steps of positioning the replacement lens between the housing of the pressure switch and the outer component of the pressure switch and securing the outer component to the housing. In a further refinement thereof, the step of securing the outer component to the housing includes the step of securing the outer component to the housing with a plurality of fasteners which extend through respective openings in the replacement lens. In still a further refinement thereof, the replacement lens includes a wiring tunnel connecting a side of the replacement lens and the cavity and the method further comprises the steps of routing wires through the wiring tunnel, the wires connected to the non-contact sensor. In yet a further refinement thereof, the steps of monitoring at least one characteristic of the current flowing between the first power line and the second power line; and monitoring at least one characteristic of the arc quenching fluid are performed by a monitoring unit separate from the pressure switch. The monitoring unit being electrically coupled to the non-contact sensor through the wires.

In yet another variation thereof, the pressure switch includes a face plate and a lens. The dial pointer is positioned between the face plate and the lens. The method further comprises the step of coupling the non-contact sensor to the pressure switch. The lens is positioned between the non-contact sensor and the dial pointer.

In another exemplary embodiment of the present disclosure, a system for monitoring a circuit breaker including a first conductive element electrically coupled to a first power line and a second conductive element electrically coupled to a second power line is provided. A connection of the first conductive element and the second conductive element is positioned in a housing including an arc quenching fluid. At least one characteristic of the arc quenching fluid being monitored by a pressure switch. The second conductive element being movable relative to the first conductive element thereby providing a closed state of the circuit breaker when the first conductive element is in contact with the second conductive element and an open state of the circuit breaker when the first conductive element is spaced apart from the second conductive element. The system comprising a monitoring unit; a magnet coupled to the dial pointer of the pressure switch, the magnet rotating with the dial pointer, an angular orientation of the dial pointer providing an indication of at least one characteristic of the arc quenching fluid; and a sensor positioned in proximity to the magnet, but spaced apart from the magnet, the sensor monitoring an angular orientation of the magnet which is indicative of the angular orientation of the dial pointer of the pressure switch, an indication of the angular orientation of the dial pointer being provided to the monitoring unit. In an example thereof, the monitoring unit is electrically coupled to at least one of the first power line and the second power line to monitor at least one characteristic of the current flowing between the first power line and the second power line.

In one variation, the pressure switch includes a face plate and a lens. The dial pointer is positioned between the face plate and the lens. The non-contact sensor being positioned between an outer surface of the lens and the dial pointer.

In another variation, the pressure switch includes a face plate and a lens. The dial pointer is positioned between the face plate and the lens. The non-contact sensor is positioned within a cavity of the lens and in alignment with the magnet. In a further variation thereof, the lens includes a terminal block. The non-contact sensor is electrically coupled to the terminal block. In a refinement thereof, the monitoring unit is electrically coupled to the non-contact sensor through the terminal block. In a further refinement thereof, the pressure switch includes an outer component and the lens is positioned between the housing of the pressure switch and the outer component of the pressure switch. In another further variation thereof, the lens includes a wiring tunnel connecting a side of the lens and the cavity, the non-contact sensor and the monitoring unit being electrically coupled through wires extending through the tunnel.

In a further example thereof, the pressure switch includes a face plate and a lens. The dial pointer is positioned between the face plate and the lens. The lens is positioned between the non-contact sensor and the dial pointer.

In a further exemplary embodiment of the present disclosure, an apparatus for generating a signal representing one of the density and pressure of gas within a high voltage circuit breaker based on a dial position of a pressure switch is provided. The pressure switch having an outer component and a housing. The pressure switch is coupled to the circuit breaker. The apparatus comprising a magnet mechanically coupled to the dial of the pressure switch; and a lens assembled into the pressure switch between the housing of the pressure switch and the outer component of the pressure switch, and circuitry to convert the detected position into an electric signal. The lens including a sensor positioned within a cavity of the lens in alignment with the magnet to detect the position of the pressure switch dial indicator from a magnetic orientation of the magnet. In one example, the magnet is carried by a clip which is configured to mechanically couple to the dial indicator of the pressure switch. In another example, the lens includes a terminal block, the non-contact sensor being electrically coupled to the terminal block. In still another example, the lens includes a wiring tunnel connecting a side of the lens and the cavity. The non-contact sensor being electrically coupled to wires extending through the tunnel.

In one embodiment, the present disclosure provides an apparatus for generating a signal representing one of the density and the pressure of gas within a high voltage circuit breaker based on a dial position of a pressure switch having an outer component and a housing and being coupled to the circuit breaker, comprising a clip configured to mechanically couple to the dial of the pressure switch, the clip including a magnet, and a lens assembled into the switch between the housing and the outer component. The lens includes a sensor positioned within a cavity of the lens in alignment with the clip magnet to detect the position of the pressure switch dial from a magnetic orientation of the magnet, and circuitry for converting the detected position into an electric signal.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

1. A method of monitoring a circuit breaker including a first conductive element electrically coupled to a first power line and a second conductive element electrically coupled to a second power line, a connection of the first conductive element and the second conductive element being positioned in a housing including an arc quenching fluid, at least one characteristic of the arc quenching fluid being monitored by a pressure switch, the second conductive element being movable relative to the first conductive element thereby providing a closed state of the circuit breaker when the first conductive element is in contact with the second conductive element and an open state of the circuit breaker when the first conductive element is spaced apart from the second conductive element, the method comprising the step of:
monitoring at least one characteristic of the arc quenching fluid by monitoring an angular orientation of a dial pointer of the pressure switch with a non-contact sensor.

2. The method of claim 1, further comprising the step of monitoring at least one characteristic of the current flowing between the first power line and the second power line.

3. The method of claim 2, wherein the step of monitoring at least one characteristic of the arc quenching fluid by monitoring a dial pointer of the pressure switch with the non-contact sensor includes the steps of:
coupling a magnet to the dial pointer, the magnet rotating with the dial pointer; and
positioning the non-contact sensor in proximity to the magnet, but spaced apart from the magnet, the non-contact sensor monitoring an angular orientation of the magnet which is indicative of the angular orientation of the dial pointer.

4. The method of claim 3, wherein the pressure switch includes a face plate and a lens, the dial pointer is positioned between the face plate and the lens, the non-contact sensor being positioned between an outer surface of the lens and the dial pointer.

5. The method of claim 4, wherein the steps of monitoring at least one characteristic of the current flowing between the first power line and the second power line; and monitoring at least one characteristic of the arc quenching fluid are performed by a monitoring unit separate from the pressure switch and the method further comprises the step of receiving with the monitoring unit an indication of the angular orientation of the dial pointer.

6. The method of claim 3, wherein the pressure switch includes a face plate and a lens, the dial pointer is positioned between the face plate and the lens, the non-contact sensor being positioned within a cavity of the lens and in alignment with the magnet.

7. The method of claim 6, wherein the lens includes a terminal block and the method further includes the step of electrically coupling the non-contact sensor to the terminal block.

8. The method of claim 7, wherein the steps of monitoring at least one characteristic of the current flowing between the first power line and the second power line; and monitoring at least one characteristic of the arc quenching fluid are performed by a monitoring unit separate from the pressure switch, the monitoring unit being electrically coupled to the non-contact sensor through the terminal block.

9. The method of claim 3, wherein the pressure switch includes a face plate and a lens and the method further comprises the steps of:
removing the lens of the pressure switch;
assembling a replacement lens to the pressure switch, the replacement lens including the non-contact sensor positioned within a cavity of the lens and in alignment with the magnet.

10. The method of claim 9, wherein the pressure switch includes an outer component and the method further comprises the step of:
removing the outer component of the pressure switch; and wherein the step of assembling the replacement lens to the pressure switch includes the steps of positioning the replacement lens between the housing of the pressure switch and the outer component of the pressure switch and securing the outer component to the housing.

11. The method of claim 10, wherein the step of securing the outer component to the housing includes the step of securing the outer component to the housing with a plurality of fasteners which extend through respective openings in the replacement lens.

12. The method of claim 11, wherein the replacement lens includes a wiring tunnel connecting a side of the replacement lens and the cavity and the method further comprises the steps of routing wires through the wiring tunnel, the wires connected to the non-contact sensor.

13. The method of claim 12, wherein the steps of monitoring at least one characteristic of the current flowing between the first power line and the second power line; and monitoring at least one characteristic of the arc quenching fluid are performed by a monitoring unit separate from the pressure switch, the monitoring unit being electrically coupled to the non-contact sensor through the wires.

14. The method of claim 3, wherein the pressure switch includes a face plate and a lens, the dial pointer is positioned between the face plate and the lens, and the method further comprising the step of coupling the non-contact sensor to the pressure switch, the lens being positioned between the non-contact sensor and the dial pointer.

15. A system for monitoring a circuit breaker including a first conductive element electrically coupled to a first power line and a second conductive element electrically coupled to a second power line, a connection of the first conductive element and the second conductive element being positioned in a housing including an arc quenching fluid, at least one characteristic of the arc quenching fluid being monitored by a pressure switch, the second conductive element being movable relative to the first conductive element thereby providing a closed state of the circuit breaker when the first conductive element is in contact with the second conductive element and an open state of the circuit breaker when the first conductive element is spaced apart from the second conductive element, the system comprising:
a monitoring unit;
a magnet coupled to the dial pointer of the pressure switch, the magnet rotating with the dial pointer, an angular orientation of the dial pointer providing an indication of at least one characteristic of the arc quenching fluid; and
a sensor positioned in proximity to the magnet, but spaced apart from the magnet, the sensor monitoring an angular orientation of the magnet which is indicative of the angular orientation of the dial pointer of the pressure switch, an indication of the angular orientation of the dial pointer being provided to the monitoring unit.

16. The system of claim 15, wherein the monitoring unit is electrically coupled to at least one of the first power line and the second power line to monitor at least one characteristic of the current flowing between the first power line and the second power line;

17. The system of claim 16, wherein the pressure switch includes a face plate and a lens, the dial pointer is positioned between the face plate and the lens, the non-contact sensor being positioned between an outer surface of the lens and the dial pointer.

18. The system of claim 16, wherein the pressure switch includes a face plate and a lens, the dial pointer is positioned between the face plate and the lens, the non-contact sensor being positioned within a cavity of the lens and in alignment with the magnet.

19. The system of claim 18, wherein the lens includes a terminal block, the non-contact sensor being electrically coupled to the terminal block.

20. The system of claim 19, wherein the monitoring unit is electrically coupled to the non-contact sensor through the terminal block.

21. The system of claim 20, wherein the pressure switch includes an outer component and the lens is positioned between the housing of the pressure switch and the outer component of the pressure switch.

22. The system of claim 18, wherein the lens includes a wiring tunnel connecting a side of the lens and the cavity, the non-contact sensor and the monitoring unit being electrically coupled through wires extending through the tunnel.

23. The system of claim 16, wherein the pressure switch includes a face plate and a lens, the dial pointer is positioned between the face plate and the lens, and the lens is positioned between the non-contact sensor and the dial pointer.

24. An apparatus for generating a signal representing one of the density and pressure of gas within a high voltage circuit breaker based on a dial position of a pressure switch having an outer component and a housing and being coupled to the circuit breaker, comprising:
a magnet mechanically coupled to the dial of the pressure switch;
a lens assembled into the pressure switch between the housing of the pressure switch and the outer component of the pressure switch, the lens including a sensor positioned within a cavity of the lens in alignment with the magnet to detect the position of the pressure switch dial indicator from a magnetic orientation of the magnet, and
circuitry to convert the detected position into an electric signal.

25. The apparatus of claim 24, wherein the magnet is carried by a clip which is configured to mechanically couple to the dial indicator of the pressure switch.

26. The apparatus of claim 24, wherein the lens includes a terminal block, the non-contact sensor being electrically coupled to the terminal block.

27. The apparatus of claim 24, wherein the lens includes a wiring tunnel connecting a side of the lens and the cavity, the non-contact sensor being electrically coupled to wires extending through the tunnel.
